(19) United States
(12) Patent Application Publication
(10) Pub. No.: US 2018/0017415 A1
(43) Pub. Date: Jan. 18, 2018

(54) DATA LOGGER AND USE OF TWO METAL WALL REGIONS OF A HOUSING OF A DATA LOGGER

(71) Applicant: Testo SE & Co. KGaA, Lenzkirch (DE)

(72) Inventor: Klaus Ketterer, Titisee-Neustadt (DE)

(73) Assignee: Testo SE & Co. KGaA, Lenzkirch (DE)

(21) Appl. No.: 15/646,560

(22) Filed: Jul. 11, 2017

(30) Foreign Application Priority Data
Jul. 15, 2016 (DE) 102016008518.5

(51) Int. Cl. G01D 9/00; H05K 5/00; H05K 1/14; H05K 1/18

(52) U.S. Cl. CPC G01D 9/005; H05K 1/144; H05K 5/0026; H05K 2201/10151; H05K 1/181; H05K 2201/10159; H05K 2201/10265; H05K 2201/042

(57) ABSTRACT

In the case of a data logger (1), it is provided to form two metal wall regions (7, 8), which are electrically isolated from one another, on a housing (6), it being possible to make electrical contact with a data connection, which has at least a first pole (4) and a second pole (5), from the outside by said metal wall regions.

### INCORPORATION BY REFERENCE

The following documents are incorporated herein by reference as if fully set forth: German Patent Application No. 102016008518.5, filed Jul. 15, 2016.

### BACKGROUND

The invention relates to a data logger, comprising at least a measurement sensor, a sensor signal processing device which is designed to process a sensor signal of the at least one measurement sensor, with a data connection comprising a first pole and a second pole being formed on the sensor signal processing device, and a housing in which the sensor signal processing device is arranged, with the housing being designed such that it is sealed to the outside.

Data loggers of this kind are known and serve to record a series of measurement values which were measured at predetermined times. For example, measurement values can be recorded in climatically unfavorable or preferably harsh environmental conditions. Temperature ranges of from −50° C. to +140° C. and/or 100% atmospheric humidity and/or overpressures of 5 bar absolute or more often have to be covered here.

This imposes particular requirements on the design of a housing. In addition, use in food sectors, for example for documenting or monitoring refrigeration chains, imposes additional requirements on the housing.

It has therefore become usual to produce the housings with a high level of sealing, for example from metal. However, transmission into the housing is often necessary for programming and reading out the data. However, radio transmission is difficult owing to the metal housings. Radio transmission can also be problematical since the energy consumption for operation would be excessively high.

### SUMMARY

The invention is based on the object of improving the functional properties of a data logger.

In order to achieve the object, one or more features of the invention are provided in a data logger. Therefore, in order to achieve the specified object in the case of a data logger of the kind described at the outset, it is provided according to the invention, in particular, that the housing has a first metal wall region and a second metal wall region, that the first metal wall region and the second metal wall region are electrically insulated from one another and are each accessible from the outside, and that the first pole makes electrical contact with the first metal wall region from the inside and the second pole makes electrical contact with the second metal wall region. Therefore, additional connection options, such as plugs or cable bushings, can be dispensed with. The housing can therefore be sealed off in a simplified manner. The receiving part, in which the data logger is mounted between two functional processes, can be designed in a structurally simple manner. The functional properties are considerably improved in this way. The invention provides the further advantage that wireless data connection, for example by radio, into the interior of the data logger is not necessary. Therefore, power consumption by the data logger can be reduced, so that, for example, a battery of the data logger can remain operational for a longer period of time.

In one refinement of the invention, it is provided that a memory for electronically storing the processed sensor signal is connected to the sensor signal processing device. Therefore, a series of measurement values can be detected and evaluated over a predetermined period of time and/or at predetermined times. In this case, it is particularly expedient when the measurement values are stored with an associated item of time information. Therefore, association with other events is possible by the correlated item of time information.

In one refinement of the invention, it is provided that the first metal wall region and the second metal wall region are formed on separate housing parts. Therefore, DC isolation between the first pole and the second pole can be established in a simple manner, for example by a coupling part which will be described in even more detail. In this case, it is particularly expedient when the housing parts are formed from metal. High classes of sealing can therefore be achieved in a simple manner. As an alternative or in addition, it can be provided that the housing parts are formed as metal/plastic hybrids, with it being possible for the metal wall regions to be formed in a metal component of the housing parts. Therefore, the manufacturing costs can be reduced.

In one refinement of the invention, it is provided that the housing parts are connected by a coupling part. In this case, it is particularly advantageous when the housing part, by way of the first metal wall region, is connected to the coupling part. This connection can be non-detachable and/or can be established, for example, by a screw connection. As an alternative or in addition, it can be provided that the housing part, by way of the second metal wall region, is connected to the coupling part. Therefore, stable fastening and sealing-off of the housing are described. This connection can be non-detachable or can be established, for example, by a screw connection. The non-detachable connections are preferably cohesive, for example adhesively bonded or welded.

In one refinement of the invention, it is provided that the coupling part forms a coupling with at least one of the housing parts. Therefore, simple assembly and disassembly can be achieved. The coupling is preferably designed in a non-detachable manner or at least such that it is secured against being unintentionally detached. In this case, it is particularly expedient when the coupling part is connected to the housing part of the first metal wall region. Therefore, this housing part can be held permanently on the coupling part, in particular in order to be sealed off to the outside. As an alternative or in addition, it can be provided that the coupling part is connected to the housing part of the second metal wall region. Therefore, this housing part can be permanently fixed, in particular such that it is sealed off to the outside, to the coupling part or even to the housing part of the first wall region. Therefore, a sealed housing can be provided in a simple manner.

In one refinement of the invention, it is provided that the coupling part electrically insulates the first wall region from the second wall region. Therefore, simple DC isolation can be achieved, in particular in the case of metal housing parts, in particular with a coupling part composed of plastic. In this case, it is particularly expedient when the electrical insulation is provided by a collar which surrounds the coupling part and is arranged between the housing part of the first metal wall region and the housing part of the second metal wall region. In this case, it is advantageous that, in the case of a substantially smooth outer contour of the housing, electrical isolation of the metal wall regions, in particular in the case of metal housing parts, can be provided.

In one refinement of the invention, it is provided that the coupling part has a passage opening through which the first pole and/or the second pole are/is electrically connected to the sensor signal processing device. Therefore, cables can be routed in the interior of the data logger in a simple manner. In addition, assembly can be executed in a simple manner by, for example, at least one pre-wired pole being inserted through the passage opening.

In one refinement of the invention, it is provided that the first pole and the second pole are formed on opposite sides of the coupling part. Therefore, physical separation of the metal wall regions can be transferred to the poles. It is particularly expedient here when at least one pole is routed, in the described manner, through a passage opening of the coupling part to the signal processing device.

In one refinement of the invention, it is provided that the sensor signal processing device is arranged on at least one printed circuit board which is placed in or on a passage opening of the coupling part, for example the abovementioned passage opening. Therefore, a space-saving arrangement can be created. Here, the at least one printed circuit board can be dimensioned such that it closes the passage opening. It is particularly expedient when the poles receive the at least one printed circuit board between them.

In one refinement of the invention, it is provided that the sensor signal processing device is arranged on at least two printed circuit boards which are electrically connected to one another by a conductor strip. Therefore, a greater number of components can be accommodated within a pre-specified cross section of the data logger. It is further advantageous that, the sensor signal processing device can be produced such that it is ready for assembly outside the abovementioned passage opening.

In one refinement of the invention, it is provided that the sensor signal processing device is arranged on at least three printed circuit boards, with two of the at least three printed circuit boards, as outer printed circuit boards, being electrically connected to a third of the at least three printed circuit boards, as middle printed circuit board, by a respective conductor strip. Therefore, the printed circuit board can be folded together in a space-saving manner and can be folded open—for example for fitting purposes. In this case, it is particularly expedient when the at least three printed circuit boards are connected to one another in such a way that the at least three printed circuit boards can be arranged in a common plane. This makes fitting easier before assembly in production methods which are known per se.

In one refinement of the invention, it is provided that the at least two printed circuit boards are arranged on the coupling part in a stacked arrangement. Here, a stacked arrangement of printed circuit boards can be characterized, for example, in that the printed circuit boards are arranged one above the other—at a distance or bearing directly one on the other—so that the individual printed circuit boards at least partially overlap. A stacked arrangement is particularly space-saving. It is particularly expedient when the at least three printed circuit boards are arranged in a stacked arrangement.

In one refinement of the invention, it is provided that the first pole and/or the second pole are/is arranged on one printed circuit board. It is particularly expedient when the first pole is formed on a different printed circuit board from amongst the abovementioned at least two or even at least three printed circuit boards to the second pole. This allows, for example, simple contact-connection in said folded-together state. In the case of the refinement with at least three printed circuit boards, it is preferably provided that the poles are each formed on one of the two outer printed circuit boards. Therefore, the poles are also easily accessible in the assembled state.

In one refinement of the invention, it is provided that a metal spring element is arranged between the first pole and the first metal wall region. Therefore, different coefficients of thermal expansion of the first wall region on the one hand and of a component which is connected to the first pole on the other hand, for example on account of different materials, can be compensated for. In this case, it is particularly expedient when the spring element is loosely inserted. This allows simple assembly. The spring element is preferably a corrugated spring ring. A corrugated spring ring has proven particularly suitable for secure contact-connection.

In one refinement of the invention, it is provided that a metal spring element is arranged between the second pole and the second metal wall region. Therefore, different coefficients of thermal expansion of the second wall region on the one hand and of a component which is connected to the second pole on the other hand, for example on account of different materials, can be compensated for. In this case, it is particularly expedient when the spring element is loosely inserted. This allows simple assembly. The spring element is preferably a corrugated spring ring. The refinement is particularly preferably combined with the above-described refinement on the first pole.

In one refinement of the invention, it is provided that the spring element of the first pole and/or the spring element of the second pole are/is (each) supported on an inwardly projecting shoulder of the respective metal wall region. Therefore, the (respective) spring element, for example a corrugated spring, can be inserted in a simple manner. A reliable contact-connection of the respective metal wall region can be established.

In order to achieve said object, the features of the independent claim which is directed at the use are provided as an alternative. Therefore, in order to achieve said object in the case of the use, it is provided according to the invention, in particular, to use two metal wall regions of a housing of a data logger, in particular of a data logger according to the invention, for electrically transmitting data through the housing. Complicated electrical plated-through holes with plugs and the like can be dispensed with. The housing can therefore be used for data transmission purposes substantially or entirely without interruption.

It is particularly expedient when a logger according to the invention, in particular as described above and/or according to one of the claims which is directed at a data logger, is used here. Therefore, the advantages described in relation to the data logger according to the invention can be utilized.

In one refinement of the invention, it is provided that stored measurement values are transmitted from the sensor signal processing device, through the housing, to the outside. Therefore, a typical application for a logger is described. The detected measurement values can be read out without the housing having to be opened.

As an alternative or in addition, it can be provided that configuration data for the sensor signal processing device is transmitted through the housing to the inside. Therefore, opening of the housing for servicing or configuration purposes can be dispensed with.

### BRIEF DESCRIPTION OF THE DRAWINGS

The invention will now be described in more detail with reference to an exemplary embodiment, but is not limited to this exemplary embodiment. Further exemplary embodiments can be obtained by combining the features of individual or several claims with one another and/or with individual or several features of the exemplary embodiment.

In the drawing, in a highly simplified, schematic form:

FIG. 1 shows a data logger according to the invention in a side view,

FIG. 2 shows the data logger from FIG. 1 in a view of the sensor tip from the front,

FIG. 3 shows the data logger from FIG. 1 in a sectional illustration along section line D-D from FIG. 1,

FIG. 4 shows an exploded illustration of the data logger from FIG. 1 in a three-dimensional oblique view from the front, and

FIG. 5 shows an exploded illustration of the data logger from FIG. 1 in a three-dimensional oblique view from the rear.

### DETAILED DESCRIPTION OF THE PREFERRED EMBODIMENTS

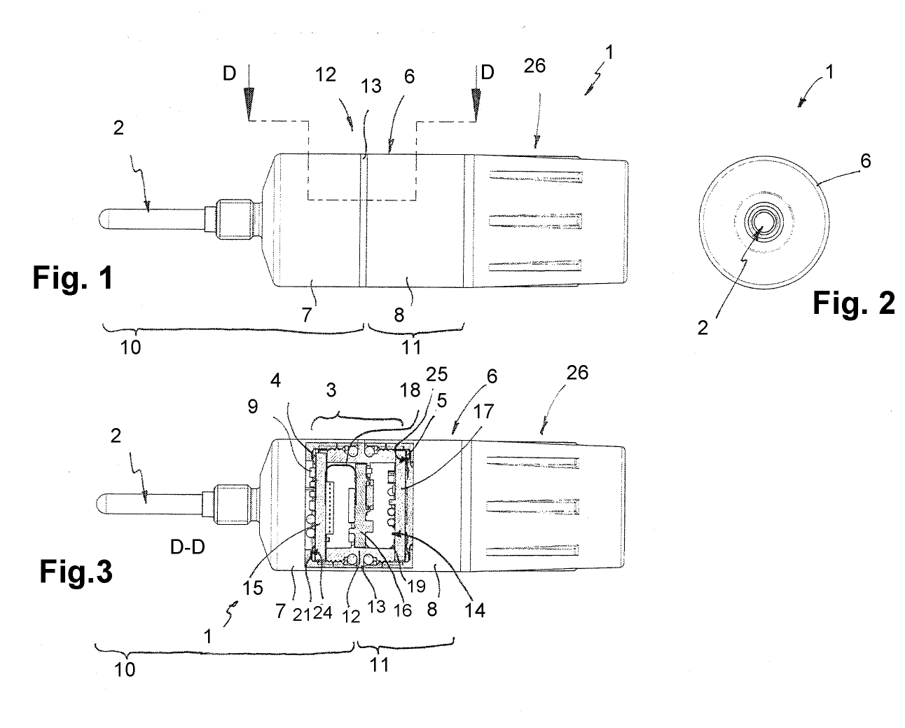

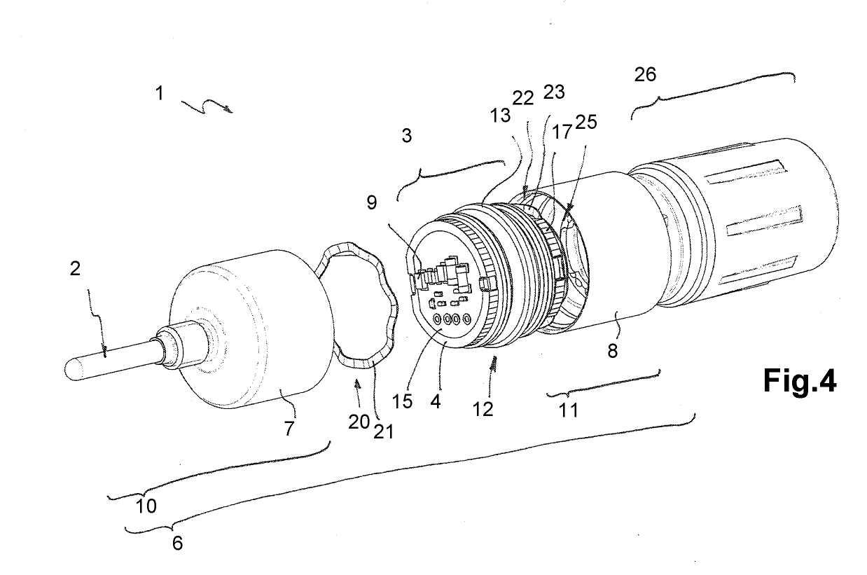

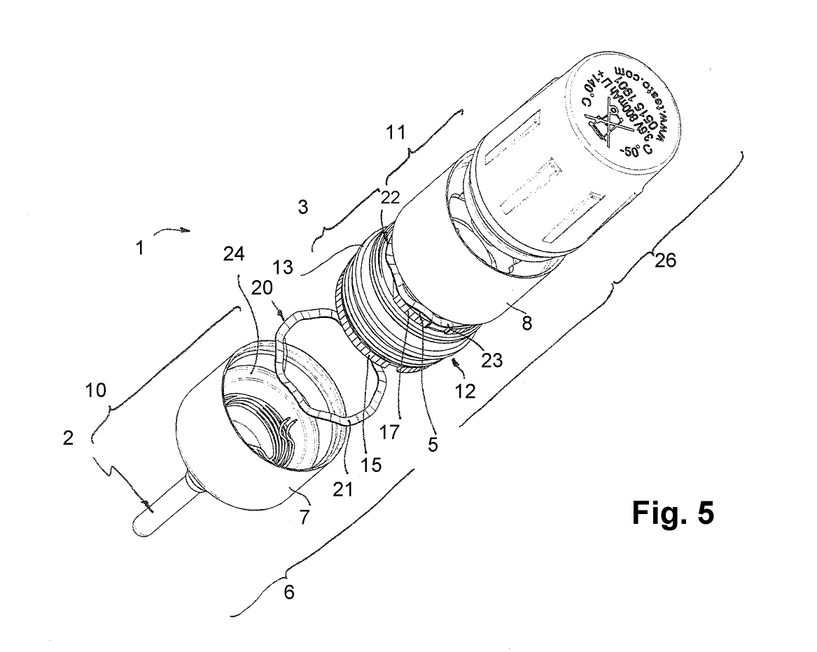

FIGS. 1 to 5 show, in different views, a data logger according to the invention which is denoted 1 overall.

The data logger 1 has at least a measurement sensor 2 and a sensor signal processing device 3. The measurement sensor 2 is connected to the sensor signal processing device 3 in a manner which is known per se in order to allow detection of measurement values at predetermined times and storage of the detected measurement values in a memory.

In addition, the sensor signal processing device 3 is designed to process the sensor signal of the at least one measurement sensor 2.

A data connection comprising a first pole 4 and a second pole 5 is formed on the sensor signal processing device 3. The data connection can have still further poles which are not shown here. The sensor signal processing device 3 and the at least one measurement sensor 2 are encapsulated by a housing 6 and are closed off in a sealed manner to the outside.

The housing 6 has a first metal wall region 7 and a second metal wall region 8 which each individually allow electrical contact-connection through the housing 6.

The first metal wall region 7 is electrically insulated from the second metal wall region 8 here, in a manner which will be described in even greater detail.

The first pole 4 makes contact with the first metal wall region 7 from the inside in a manner which will be described in even greater detail. The second pole 5 makes contact with the second metal wall region 8 electrically from the inside in a similar manner.

Therefore, the first pole 4 and the second pole 5 are electrically accessible from the outside.

The sensor signal processing device 3 is electrically connected to a memory 9 which is connected to the sensor signal processing device 3 for electronically storing the processed sensor signal together with an associated item of time information, that is to say the time-correlated measurement values.

In the exemplary embodiment, the first metal wall region 7 is formed as part of an integral metal housing part 10. Similarly, the second metal wall region 8 is formed as part of a likewise integral metal housing part 11. The housing parts 10, 11 are connected to one another by a coupling part 12 here. The coupling part 12 electrically insulates the wall regions 7, 8 from one another by forming a collar 13 which surrounds the coupling part 12. In the assembled state, the collar 13 is arranged between the housing parts 10, 11 and therefore electrically isolates said housing parts from one another.

A continuous passage opening 14 is formed in the coupling part 12, the first pole 4 and the second pole 5 being electrically connected to the sensor signal processing device 3 through said passage opening. The first pole 4 and the second pole 5 are situated on opposite sides of the coupling part 12 here.

The sensor signal processing device 3 is spread over three printed circuit boards 15, 16, 17 which are inserted into the passage opening 14 of the coupling part 12.

Here, the outer printed circuit boards 15, 17 are electrically connected to the middle printed circuit board 16 by means of a respective flexible conductor strip 18, 19. The flexible conductor strips 18, 19 are arranged on mutually opposite sides of the middle printed circuit board 16 and on corresponding sides of the outer printed circuit boards 15, 17 in such a way that the three printed circuit boards 15, 16, 17 can be arranged in a common plane.

The printed circuit boards 15, 16, 17 on the coupling part 12 form a stacked arrangement in the inserted state.

A metal spring element 20 in the form of a corrugated spring 21 is arranged between the first pole 4 and the associated first metal wall region 7. Similarly, a spring element 22 in the form of a corrugated spring 23 is formed between the second pole 5 and the associated second metal wall region 8. Here, the spring elements 20, 22 are loosely placed on the coupling part 12 and loosely placed on the housing parts 10, 11.

A shoulder 24, 25 against which the respective spring element 20, 22 rests is formed in the interior of the housing parts 10, 11 in each case.

Therefore, during operation, the metal wall regions 7, 8 are used to make contact with the poles 4, 5 from the outside, without the housing 6 having to be opened.

Here, for example, stored measurement values can be read out from the memory 9 and/or configuration data for the sensor signal processing device 3 can be transmitted through the housing 6 to the inside.

A battery part 26 is detachably connected to the housing 6.

In the case of the data logger 1, it is provided to form two metal wall regions 7, 8, which are electrically isolated from one another, on a housing 6, it being possible to make electrical contact with a data connection, which has at least a first pole 4 and a second pole 5, from the outside by said metal wall regions.

### LIST OF REFERENCE SYMBOLS

1 Data logger
2 Measurement sensor
3 Sensor signal processing device
4 First pole
5 Second pole
6 Housing
7 First metal wall region
8 Second metal wall region
9 Memory
10 Housing part
11 Housing part
12 Coupling part
13 Collar
14 Passage opening
15 (Outer) printed circuit board
16 (Middle) printed circuit board
17 (Outer) printed circuit board
18 Flexible conductor strip
19 Flexible conductor strip
20 Metal spring element
21 Corrugated spring
22 Metal spring element
23 Corrugated spring
24 Shoulder
25 Shoulder
26 Battery part

1. A data logger (1), comprising at least a measurement sensor (2), a sensor signal processing device (3) which is designed to process a sensor signal of the at least one measurement sensor (2), a data connection comprising a first pole (4) and a second pole (5) being formed on the sensor signal processing device (3), a housing (6) in which the sensor signal processing device (3) is arranged, with the housing (6) being designed such that it is sealed to outside, the housing (6) comprises a first metal wall region (7) and a second metal wall region (8), the first metal wall region (7) and the second metal wall region (8) are electrically insulated from one another and are each accessible from the outside, and the first pole (4) makes electrical contact with the first metal wall region (7) from inside and the second pole (5) makes electrical contact with the second metal wall region (8).

2. The data logger (1) as claimed in claim 1, further comprising a memory (9) configured to electronically store a processed sensor signal connected to the sensor signal processing device (3).

3. The data logger (1) as claimed in claim 1, wherein the first metal wall region (7) and the second metal wall region (8) are formed on separate housing parts (10, 11).

4. The data logger (1) as claimed in claim 1, wherein the housing parts (10, 11) are connected by a coupling part (12).

5. The data logger (1) as claimed in claim 4, wherein the coupling part (12) electrically insulates the first wall region (7) from the second wall region (8)

6. The data logger (1) as claimed in claim 5, wherein the coupling part (12) has a passage opening (14) through which at least one of the first pole (4) or the second pole (5) is electrically connected to the sensor signal processing device (3).

7. The data logger (1) as claimed in claim 4, wherein the sensor signal processing device (3) is arranged on at least one printed circuit board (15, 16, 17) which is placed in or on a passage opening (14) of the coupling part (12).

8. The data logger (1) as claimed in claim 4, wherein the sensor signal processing device (3) is arranged on at least two printed circuit boards (15, 16, 17) which are electrically connected to one another by a conductor strip (18).

9. The data logger (1) as claimed in claim 8, wherein the at least two printed circuit boards (15, 16, 17) are arranged on the coupling part (12) in a stacked arrangement.

10. The data logger (1) as claimed in claim 8, wherein at least one of the first pole (4) or the second pole (5) is arranged on one of the printed circuit boards (15, 16, 17).

11. The data logger (1) as claimed in claim 1, further comprising at least one of a first metal spring element (20) arranged between the first pole (4) and the first metal wall region (7), or a second metal spring element (22) arranged between the second pole (5) and the second metal wall region (8).

12. The data logger (1) as claimed in claim 11, wherein at least one of the first spring element (20) of the first pole (4) or the second spring element (22) of the second pole (5) is supported on an inwardly projecting shoulder (24, 25) of the respective metal wall region (7, 8).

13. The data logger (1) as claimed in claim 1, wherein the two metal wall regions (7, 8) of the housing (6) are adapted for electrically transmitting data through the housing.

14. The data logger (1) as claimed in claim 13, wherein at least one of stored measurement values are transmitted from the signal processing device (3), through the housing (6), to the outside, or configuration data for the signal processing device (3) is transmitted through the housing (6) to the inside.

15. The data logger (1) as claimed in claim 2, wherein the memory (9) is configured to electronically store an associated item of time information with the processed sensor signal.

16. The data logger (1) as claimed in claim 4, wherein the housing parts (10, 11) are connected by the first metal wall region (7) being connected to the coupling part (12) in a non-detachable manner and the second metal wall region (8) being connected to the coupling part (12) in a non-detachable manner.

17. The data logger (1) as claimed in claim 4, wherein a collar (13) surrounds the coupling part (12) and is arranged between the housing part (10) having the first metal wall region (7) and the housing part (11) having the second metal wall region (8) and electrically insulates the first wall region (7) from the second wall region (8).

18. The data logger (1) as claimed in claim 5, wherein the first pole (4) and the second pole (5) are formed on opposite sides of the coupling part (12).

19. The data logger (1) as claimed in claim 1, wherein the sensor signal processing device (3) is arranged on at least three printed circuit boards (15, 16, 17), and two of the at least three printed circuit boards (15, 16, 17), as outer printed circuit boards (15, 17), are electrically connected to a third of the at least three printed circuit boards (15, 16, 17), as a middle printed circuit board (16), by a respective conductor strip (18, 19).
